(19) United States
(12) Patent Application Publication
(10) Pub. No.: US 2026/0321330 A1
(43) Pub. Date: Oct. 15, 2026

(54) Circuits and Methods for Calibrating a Memory Die with Integrated Processor

(71) Applicant: Rambus Inc., San Jose, CA (US)

(72) Inventor: Dongyun Lee, Sunnyvale, CA (US)

(21) Appl. No.: 19/632,358

(22) Filed: Mar. 29, 2026

Related U.S. Application Data
(60) Provisional application No. 63/788,354, filed on Apr. 14, 2025.

(51) Int. Cl. G11C 29/12; G11C 29/52

(52) U.S. Cl. CPC G11C 29/1201; G11C 29/12005; G11C 29/52

(57) ABSTRACT

A memory system includes a DRAM die with an integrated processor. The die includes banks of memory and local processors. The banks are accessible by both the local processors and a remote host. The local processor has relatively direct access to the memory banks for improved efficiency and speed performance for some classes of data-intensive applications, such as artificial intelligence and big data analytics. The supply voltage and clock speed of the processor are independent of the other components of the DRAM die and can be calibrated independently optimize the power and speed of on-die processing.

### FIELD OF THE INVENTION

The subject matter presented herein relates generally to semiconductor memory devices and, more particularly, to a processor integrated with dynamic random-access memory (DRAM).

### BACKGROUND

Dynamic Random Access Memory (DRAM) is a cornerstone of computing systems, providing high-density, cost-effective storage for data accessed by central processing units (CPUs), graphics processing units (GPUs), and other external processors. Data stored in DRAM is transferred across a memory bus to the processor for computation, then returned to memory as needed. This approach, while effective for traditional workloads, increasingly encounters limitations as data-intensive applications—such as artificial intelligence, big data analytics, and high-performance computing—demand ever-greater bandwidth and lower latency.

A primary bottleneck in these systems is the “memory wall,” a disparity between the rapid increase in processor performance and the relatively slow improvement in memory access speeds. The physical separation of memory and processing units necessitates frequent, high-volume data transfers, consuming significant power and introducing latency that degrades system performance. Processing-in-Memory (PIM)—integrating processors with memory—has emerged as a promising paradigm to address this limitation.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 depicts a memory system 100 in which a DRAM die 105 with multiple core slices 110 service read and write requests from a host controller 115.

FIG. 2 depicts two waveform diagrams 200 and 210 illustrating signal timing for respective high-and low-speed processor modes.

FIG. 3 is a flowchart 300 illustrating the operation of system 100 of FIG. 1 in accordance with one embodiment.

### DETAILED DESCRIPTION

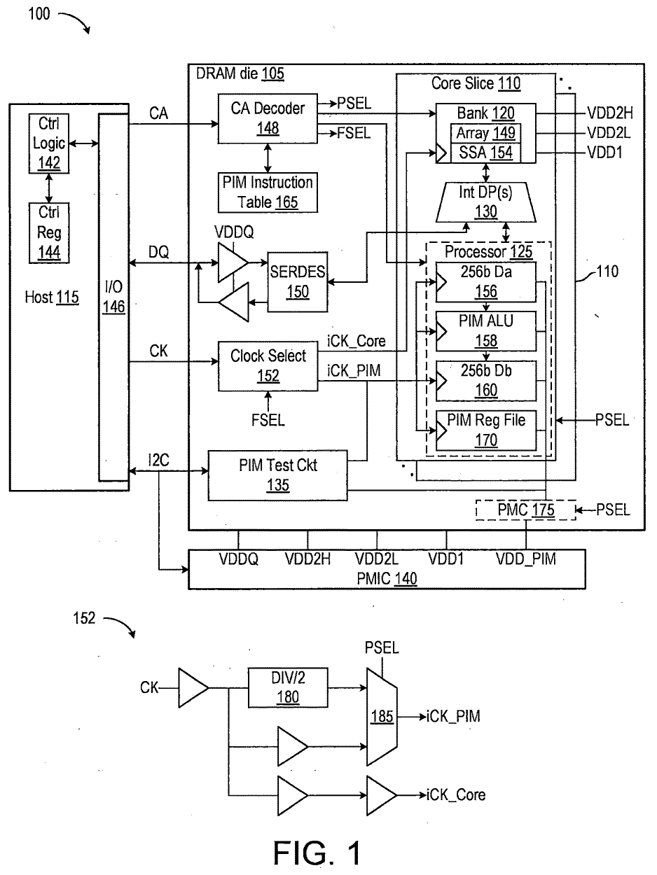

FIG. 1 depicts a memory system 100 in which a DRAM die 105 with multiple core slices 110 service read and write requests from a host controller 115. Each core slice 110 includes a memory bank 120 for storing data from host controller 115 and a local processor 125 with relatively direct access to memory bank 120 via an intermediate data path 130. Local processor 125 improves efficiency and speed performance for some classes of data-intensive applications, such as artificial intelligence and big data analytics. The supply voltage and clock speed of processor 125 are independent of the other components of die 105 and can be calibrated independently to optimize power and speed. An integrated test circuit 135 issues performance metrics that can be used to adjust the clock speed and supply voltage of processor 125. The performance metrics can include delays and error rates.

Host 115 supports dynamic frequency and power scaling for PIM 125. Power consumption is typically a function of both frequency and the square of supply voltage. A processor power savings of approximately fifty percent can thus be obtained using a supply voltage of approximately 71% or a clock signal with twice the period. Host 115 can direct processor 125 to function in four discrete modes, one for each combination of relatively low and high PIM supply voltages on a supply node VDD_PIM and relatively low and high frequencies for a PIM clock signal iCK_PIM. Supply voltage and timing for processor 125 are adjusted independently of one another and of the other components of die 105.

Memory system 100 includes a power-management integrated circuit (PMIC) 140 under the control of host 115 via an I2C bus (Inter-Integrated Circuit bus), a widely used serial communication protocol designed for short-distance, low-to-moderate-speed data transfer between integrated circuits (ICs) on the same PCB or within a small system. Host controller 115 includes control logic 142, a control register 144, and input/output (I/O) interface 146. I/O interface 146 is connected to DRAM die 105 via command/address (CA) port CA, which control logic 142 uses to issue commands (e.g. read and write commands) to locations in core slices 110 specified by addresses that accompany the commands. Control logic 142 can also direct commands to processor 125 to e.g. read and process data from bank 120 and store the results back to the memory or provide them to host 115. External data port DQ handles the movement of data signals between host 115 and die 105, and clock port CK issues a clock signal from host 115 to synchronize host 115 with DRAM die 105. Other well-known ports and signals are omitted for brevity.

The DRAM side of the communication channel includes a CA decoder 148, a serializer/deserializer (SERDES) 150, and a clock-select circuit 152. CA Decoder 148 interprets command and address signals received via the CA (Command/Address) port from host 115. Commands include Activate, Read, Write, and Precharge; each address directed to a slice 110 specifies a row and column in an array 149 of memory cells (not shown) in banks 120. CA decoder 148 decodes these commands into internal control signals that manage memory transactions. SERDES 150 manages high-speed data transfers between a relatively wide internal data path to core slices 110 and narrower external data (DQ) pins of interface DQ. In the read direction, serialization converts wide internal data (e.g., 64 bits from a sense-amplifier array 154) into a serial stream for output on DQ during reads, matching the external bus width (e.g., eight eight-bit bursts). Deserialization performs the reverse in the write direction. Finally, clock-select circuit 152 produces and distributes internal clock signals based on external clock signal CK to synchronize DRAM operations. This example includes two clock signals, a memory (core) clock signal iCK_Core for timing bank operations of e.g. memory-cell array 149 and sense-amplifier array 154 and a PIM clock signal iCK_PIM for timing processing operations of processor 125.

Processor 125 includes, in this example, a 256b synchronous input register 156 connected via internal data path 130 to SSA 154 to receive 256 parallel data bits, also called a “cacheline”; an arithmetic logic unit (ALU) 158 that performs arithmetic and logical operations on the data in register 156; and a 256b synchronous output register 160 that communicates outputs from ALU 158 back to the ALU inputs or to SSA 154 to be written back to array 149. ALU 158 can support single-instruction, multiple-data (SIMD) and floating-point (FP) operations. Registers 156 and 160 can also communicate with host 115 via internal data path 130 and serdes 150.

Bank 120 and data path 130 can be an implementation of a dual-port memory that allows host 115 and processor 125 to access array 149 simultaneously. Dual-port DRAM has two independent access ports, each with its own set of address, data, and control lines, enabling host 115 and processor 125 to interact with bank 120 concurrently without interference. Each port can operate at different speeds, data widths, or both. Dual-port DRAM architectures are well known so a detailed discussion is omitted.

DRAM die 105 includes a PIM instruction table 165 that stores a list of operations that processor 125 can perform on data stored in bank 120. Each table entry has an index and a detailed instruction. Host 115 issues indexed commands that decoder 148 decodes to call upon table 165 to provide instructions that cause processor 125 to perform logical and arithmetic operations on addressed variables (e.g. multiply the data at addresses A and B and store the product at address A). Table 165 can list multi-cycle operations, which involve several steps each taking one or more clock cycles to fully execute. Vector or bulk operations can be supported so that a single command from host 115 can manipulate large arrays of data in ways common for machine learning and artificial intelligence. Load instructions can also move data between array 149 and a PIM register file 170 that provides fast, local storage of e.g. 640 bytes per PIM block. PIM Register file 170 can include instruction, vector, and scalar registers. Processor 125 interprets selected entries in instruction table 165 to fetch operands from array 149 into register 156 (via internal data path 130), processes them using ALU 158 or some other processing element, and writes results back to array 149.

Clock-select circuit 152 provides timing references for synchronizing communication between bank 120 and both SERDES 150 and processor 125. Host 115 controls clock source 152, processor 125, and PMIC 140 to select different performance modes for processor 125, modes that trade speed performance for power efficiency and error reduction. In a low-speed, low-power mode, clock-select circuit 152 provides a relatively low-frequency clock signal iCK_PIM and PMIC 140 provides a relatively low processor supply voltage VDD_PIM. Processor 125 then communicates and processes data signals with bank 120 at a relatively slow and power-efficient rate. In a low-speed, high-power mode, clock-select circuit 152 provides the same relatively low-frequency clock signal iCK_PIM but PMIC 140 increases supply voltage VDD_PIM. The same relatively low and high supply voltages on node VDD_PIM can be used in a relatively high-speed mode in which clock-select circuit 152 doubles the frequency of processor clock signal iCK_PIM, matching the frequency of memory clock signal iCK_Core in this example. DRAM die 105 can include an integrated power-management circuit 175 that controls processor voltage VDD_PIM in other embodiments, in which case decoder 148 can issue the same power-select signal PSEL to each circuit on die 105 impacted by the change in processor power modes.

FIG. 1 includes a simple circuit diagram of clock-select circuit 152. A clock divider 180 divides clock signal CK from host 115 by two. A frequency-select signal FSEL from decoder 148 directs a multiplexer 185 to pass either this divided clock signal or the original clock signal CK as internal processor clock signal iCK_PIM. Buffers in the clock paths of clock-select circuit 152 phase match clock signals iCK_PIM and iCK_Core in both modes.

PIM test circuit 135 communicates metrics of PIM performance to host 115 via test port I2C or responsive to commands to decoder 148. In one embodiment, test circuit 135 includes a ring oscillator made of XOR logic gates and latches, replicating the longest data path in processor 125. The oscillation frequency of this replica provides a measure of the speed performance of processor 125. If the speed performance is inadequate in a given mode, the frequency can be lowered or the supply voltage increased. Memory controller 115 can cause different supply voltages to be applied to processor 125 by e.g. selecting among voltage rails, commanding PMIC 140 via the I2C bus, or commanding PMC 175 via the I2C bus or via command/address bus CA.

PIM test circuit 135 can also sense the error rate of processor 125 and change the performance setting for processor 125 to achieve the lowest power usage for an acceptable error rate. In one embodiment, PIM test circuit 135 has access to a PIM pipeline stage (not shown) that fetches new operands while ALU 158 considers a prior set. Test circuit 135 can run test operations through the pipeline stage while monitoring for errors, such as bit flips, incorrect computations, or timing-related failures. Error messages can be reported back to host 115, which can use this feedback to adjust operating conditions (e.g., processor voltage and frequency) or flag faulty components.

PIM test circuit 135 allows processor 125 to be tested and recalibrated in the mission mode (in the normal operating mode rather than a test mode). Testing can use a parity code, such as a Berger code. Inserting additional cycles with bit-shifted inputs (e.g., a logical left or right shift) changes data patterns to help expose data-dependent faults.

Processor 125, including ALU 158, can be instantiated using DRAM peripheral devices, which provide considerably reduced processing performance than integrated circuits optimized for processing. DRAM peripheral devices tend to be larger and slower, which aggravates power consumption. Using elements of DRAM peripheral devices to instantiate processor 125 thus results in higher local power consumption. This disadvantage can be more than offset by the relatively short bus length to bank 120 and the parallel processing afforded by the large number of PIM processors.

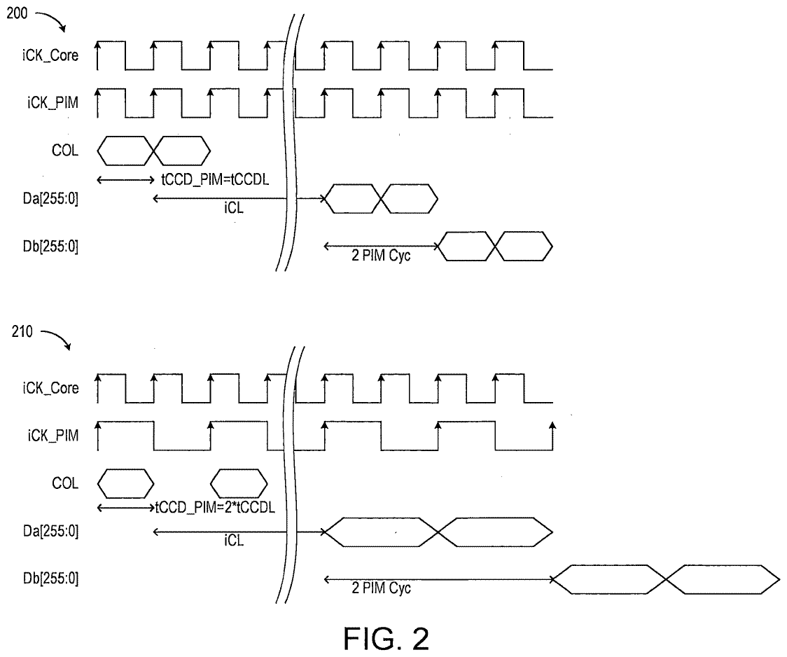

FIG. 2 depicts two waveform diagrams 200 and 210 illustrating signal timing for respective high-and low-speed processor modes. In the high-speed mode, processor clock signal iCK_PIM is of the same phase and frequency as memory clock signal iCK_Core. In the low-speed mode, processor clock signal iCK_PIM is of the same phase and half the frequency as memory clock signal iCK_Core. Clock signals iCK_PIM and iCK_Core are phase aligned for all frequencies of iCK_PIM so that the timing paths between banks 120 and processor 125 are unaffected by the frequency change. Gaps are inserted between column accesses in the low-speed mode to accommodate the reduced data bandwidth. These gaps are multiples of the period of clock signal iCK_Core, one times (1×) that clock period in this embodiment.

Column accesses COL are separated by a minimum column-to-column delay tCCD that must elapse between consecutive column access commands (e.g., READ-to-READ or WRITE-to-WRITE) to the same bank. In the high-performance mode, the column-to-column delay tCCD_PIM for processor 125 is the same as the column-to-column delay tCCDL for accesses by host 115. The column latency iCL—the time between a column access command COL and when the data from the specified column is available on the processor's data bus (for a read) is the same for both modes. In the write direction, however, the column latency is twice as long in the low-performance mode because it is a function of the slower processor (PIM) cycle rate.

PIM clock iCK_PIM has more frequency settings in other embodiments. For example, some embodiments support PIM clock signals with periods 1×, 2×, 3×, 4× . . . that of the memory clock signal. These or other embodiments support periods that are non-integer multiples of the memory clock signal using e.g. a clock domain crossing FIFO, which may result in additional delay and power consumption. Likewise, more supply-voltage options can be made available.

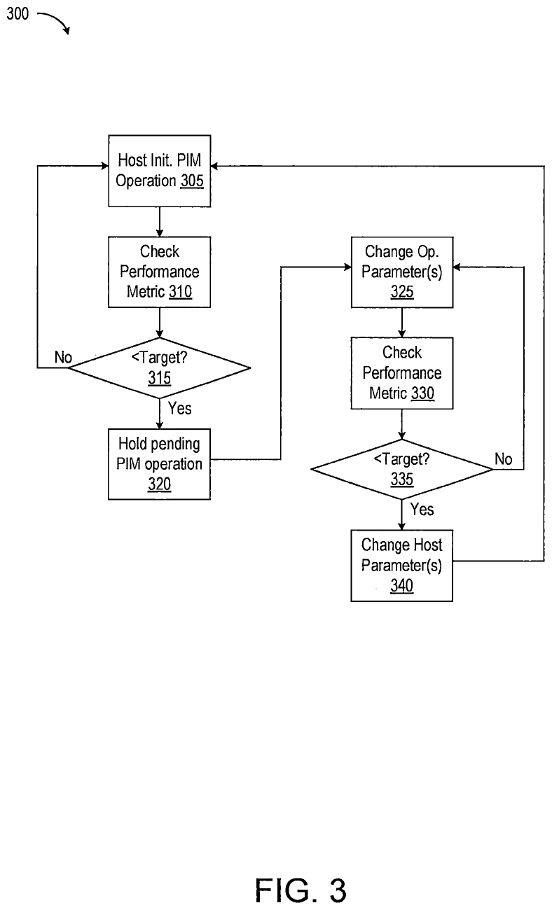

FIG. 3 is a flowchart 300 illustrating the operation of system 100 of FIG. 1 in accordance with one embodiment. To start, host 115 initiates a PIM operation (305), such as a vector-matrix multiplication (or a specific case like a dot product of two vectors). A single dot product might involve hundreds or thousands of elements (e.g., in large neural networks). Before engaging in this process, DRAM die 105 directs PIM test circuit 135 to run a performance check (310). This check can be instigated as part of the command from host 115 or as a separate command. The check can also be instigated periodically or by a change in e.g. temperature, voltage, or error rate sensed at or by DRAM die 105. Performance checking can be done in parallel with mission-mode operation and can be executed more or less frequently to achieve a desired tradeoff between efficacy and power consumption.

Per decision 315, if the measured parameter from test circuit 135 is less than a target value, meaning processor performance is adequate, then processor 125 proceeds with the requested operation and the process returns to step 305 to await the next request. If the performance is inadequate, however, the requested PIM operation is held (320) and an operating parameter is changed (325). In general, changing an operating parameter involves adjusting a supply voltage with a fixed step or a clock frequency among allowed values. Preset combinations of operating parameters can also be used. In this example, PIM supply voltage VDD_PIM is increased at step 325 and performance is rechecked (330). Per decision 335, if the tested parameter still fails to reach the target value, the PIM clock rate is reduced to relax timing requirements (step 325). If one or both parameter changes causes system 100 to meet the target requirement, DRAM die 105 updates the operational parameters for processor 125 and alerts host 115 (340). Control logic 142 updates control register 144 with the changed values to allow host 115 to optimize command queuing and reordering accordingly. Like performance checking, register updates can be done in parallel with mission-mode operation and can be executed more or less frequently.

Host 115 can issue commands to collect PIM performance metrics, configure DRAM for collecting performance metrics, run PIM house-keeping (e.g. holding PIM operation and clearing a processing pipeline). Host 115 can also optimize or reschedule job queues after updating PIM-related timing parameters. Control register 144 can store PIM performance metrics for each slice 110. Control register 144 can apply affected changes to DRAM die 105 and PMIC 140 via the I2C bus or can affect changes to DRAM 105 by writing to mode registers on DRAM die 105.

While the invention has been described with reference to specific embodiments thereof, it will be evident that various modifications and changes may be made thereto without departing from the broader spirit and scope of the invention. For example, the ratio of PIM processors to memory banks can be other than 1:1, and integrated processors can support memories other than DRAMs. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. § 112.

What is claimed is:

1. An integrated-circuit memory die comprising:
a memory bank to store data;
an internal data path to communicate the data to and from the memory bank;
an external data port coupled to the internal data path to communicate the data to and from a host external to the memory die via the internal data path;
a processor integrated with the memory bank and coupled to the internal data path to communicate the data to and from the memory bank via the internal data path, the processor including a processor-clock node to receive a processor clock signal and a processor supply node to receive a processor supply voltage; and
a test circuit to measure a performance metric of the processor.

2. The memory die of claim 1, wherein the test circuit comprises a ring oscillator.

3. The memory die of claim 1, wherein the memory bank includes a core-clock node to receive a memory clock signal and a memory-voltage node to receive a memory supply voltage.

4. The memory die of claim 3, further comprising a clock generator to generate the processor clock signal of a processor clock period and the memory clock signal of a memory clock period different from the processor clock period.

5. The memory die of claim 4, wherein the processor clock period is a multiple of the memory clock period.

6. The memory die of claim 4, the clock generator including a clock-select circuit to change the processor clock period to a second processor clock period.

7. The memory die of claim 1, wherein the memory bank includes an array of sense amplifiers, and wherein the internal data path alternatively couples the sense amplifiers to the processor and the external data port.

8. The memory die of claim 1, wherein the memory bank includes first and second arrays of sense amplifiers and the internal data path couples the first array of sense amplifiers to the external data port and the second array of sense amplifiers to the processor.

9. The memory die of claim 1, further comprising integrated power-management circuitry to provide the processor supply voltage.

10. The memory die of claim 9, the power-management circuitry to receive a power-management signal to change the processor supply voltage.

11. The memory die of claim 1, wherein the processor supply node is not connected to any of the memory bank, the internal data path, and the external data port.

12. A method of controlling speed performance of an integrated-circuit memory device having a memory bank and an integrated processor communicatively coupled to the memory bank, the method comprising:
loading first data from the memory bank to the processor and processing the first data at a first combination of processor clock frequency and processor supply voltage;
receiving a performance command at the memory device, the performance command causing the processor to enter a low-performance mode;
loading second data from the memory bank to the processor in the low-performance mode; and
processing the second data at a second combination of processor clock frequency and processor supply voltage in the low-performance mode.

13. The method of claim 12, wherein the first combination of processor clock frequency and processor supply voltage has a higher processor clock frequency than the second combination.

14. The method of claim 13, wherein the first combination of processor clock frequency and processor supply voltage has a higher processor supply voltage than the second combination.

15. The method of claim 12, wherein the loading of second data comprises inserting gaps of a gap duration between column accesses.

16. The method of claim 15, further comprising clocking the memory at a memory-clock period, wherein the gap duration is an integer multiple of the memory-clock period.

17. The method of claim 12, further comprising decoding the performance command and loading an instruction table for the integrated processor responsive to the performance command.

18. The method of claim 12, further comprising detecting an error of the processor and issuing an error message to a host controller responsive to the error.

19. The method of claim 18, wherein the host controller issues the performance command responsive to the error messages.

20. The method of claim 12, further comprising periodically measuring performance of the processor.

21. The method of claim 12, further comprising adjusting operating parameters for the memory bank responsive to the processor clock frequency.
